(19) United States
(12) Patent Application Publication
(10) Pub. No.: US 2006/0290546 A1
(43) Pub. Date: Dec. 28, 2006

(54) Wideband digital receiver architecture

(75) Inventors: William C. Phillips, Elkridge, MD (US); Mark W. Brown, Ellicott City, MD (US); Thomas K. Lisle, Ellicott City, MD (US); Michael J. Capparelli, Sykesville, MD (US); Daikim K. Loo, Pasadena, MD (US); Michael J. Juengst, Glen Burnie, MD (US)

Correspondence Address: ROTHWELL, FIGG, ERNST & MANBECK, P.C., 1425 K STREET, N.W., SUITE 800, WASHINGTON, DC, 20005, US

(73) Assignee: NORTHROP GRUMMAN CORPORATION, Los Angeles, CA (US)

(21) Appl. No.: 11/165,529

(22) Filed: Jun. 24, 2005

(51) Int. Cl. H03M 1/06

(52) U.S. Cl. 341/119

(57) ABSTRACT

An integrated circuit architecture on a single chip, including a module for digital IQ generation; a module for LO synthesis; a digital mixing module; a multi-stage filtering and decimation module; a passband equalization module; an integration module; and a DC offset adjustment module.

### BACKGROUND OF THE INVENTION

1. Field of the Invention

The present invention relates generally to radio frequency (RF) devices, and more particularly, the present invention relates to an universal digital receiver architecture.

2. Description of the Related Art

Modern radar receivers for various applications, such as air surveillance or ground surveillance, have very differing requirements. It is known that digital receivers are required for modern radar systems. It is generally desired that such receivers have a low cost and minimize size, weight and the amount of power required.

It is well known that application specific integrated circuits (ASICs) provide the lowest power, the highest level of integration with other components, and the lowest recurring cost of any available digital technology. Conversely, commercially available alternatives usually require more power (e.g., 10-100 times less efficient) and offer less capability than ASICs because of their generalized nature. However, ASICs suffer from the problem that they have very high non-recurring engineering (NRE) costs, such as costs associated with the initial design, mask fabrication, etc.

Because of the high NRE of ASIC's, there is a need for improved digital receiver designs that are more efficient than commercial solutions yet can be used for multiple applications in order to reduce the NRE.

### SUMMARY OF THE INVENTION

According to an embodiment of the present invention, an integrated circuit architecture on a single chip is provided that includes a plurality of functions. The architecture includes a module for digital IQ generation, a module for LO synthesis, a digital mixing module, a multi-stage filtering and decimation module, a passband equalization module, an integrate & dump module, and a DC offset adjustment module.

According to an embodiment of the present invention, an integrated circuit architecture on a single chip is provided that includes an input MUX means for providing front-end interface to the input signals and clock signals. The architecture also includes control interface means for providing electrical interfaces to allow an external controller to reset the chip, load coefficients, configure the chip by enabling or disabling bypass setting on a plurality of functions, switch between at least two processing modes, switch between at least two A/D inputs, and test the chip. The architecture also includes clock distribution means for accepting a selected input and distributing copies of the selected input throughout the chip, and generating a utility clock signal (UTILCLK) output from the chip to be used by other external devices to synchronize to output data of the chip. The architecture also includes output MUX means for providing an electric interface to external circuits that receive signals from the chip, and selectively providing either single-ended or differential signals for all outputs. The architecture also includes tuner filter means for accepting demuxed data from the input MUX means and performing digital tuning and filtering.

According to an embodiment of the present invention, a reconfigurable filter and decimate circuit is provided. The circuit includes a signal input, an adder having a plurality of signal inputs and a signal output, means for demultiplexing a signal received into a plurality of sampled signals, a plurality of FIR filters each having a number of taps, and switching means for coupling the plurality of sampled signals with the plurality of FIR filters and with the plurality of signal inputs to the adder, and for decimating the input signal a number of times. For each number of times, the output of the adder is filtered by the same number of taps.

According to an embodiment of the present invention, a fast FIR filter is provided. The fast FIR filter includes a demultiplexer configured to receive an input signal and to separate the signal into a plurality of signals. The filter also includes filter means for filtering the plurality of signals and outputting a plurality of filtered signals. The filter also includes multiplexer for combing the plurality of filtered signals into a single output signal. The filter means processes each of the plurality of signals at a rate a plurality of times slower than the input rate of the input signal without decimation of the input signal and without loss of bandwidth of the input signal.

According to an embodiment of the present invention, a digital IQ signal generation circuit (DIQ) is provided. The DIQ includes demultiplexing means for separating a real input signal into first, second, third and fourth signals. The DIQ also includes inverter means for inverting the third and fourth signals. The DIQ also includes low pass FIR filter means for filtering the first, second, third and fourth signals. The DIQ also includes multiplexing means for combining the filtered first and third signals and for combining the second and fourth signals, in order to generate I and Q sampled signal channels at one half an input data rate of the real input signal. The low pass FIR filter means processes signals at one quarter the input data rate of the real input signal.

Further applications and advantages of various embodiments of the present invention are discussed below with reference to the drawing figures.

### BRIEF DESCRIPTION OF THE DRAWINGS

FIG. 1 is a diagram of a universal ASIC design for a wideband digital receiver according to an embodiment of the present invention;

FIG. 2 is a diagram of a former low-speed DIQ circuit;

FIG. 3 is a diagram of an implementation of a high speed (2R) FIR filter according to an embodiment of the present invention;

FIG. 4 is a diagram of a high speed DIQ circuit according to an embodiment of the present invention;

FIG. 5 is a diagram of a high speed (4R) FIR Filter according to an embodiment of the present invention; and

FIG. 6 is a diagram of a programmable polyphase decomposition circuit according to an embodiment of the present invention.

### DETAILED DESCRIPTION OF THE PREFERRED EMBODIMENTS

While the present invention may be embodied in many different forms, a number of illustrative embodiments are described herein with the understanding that the present disclosure is to be considered as providing examples of the principles of the invention and such examples are not intended to limit the invention to preferred embodiments described herein and/or illustrated herein.

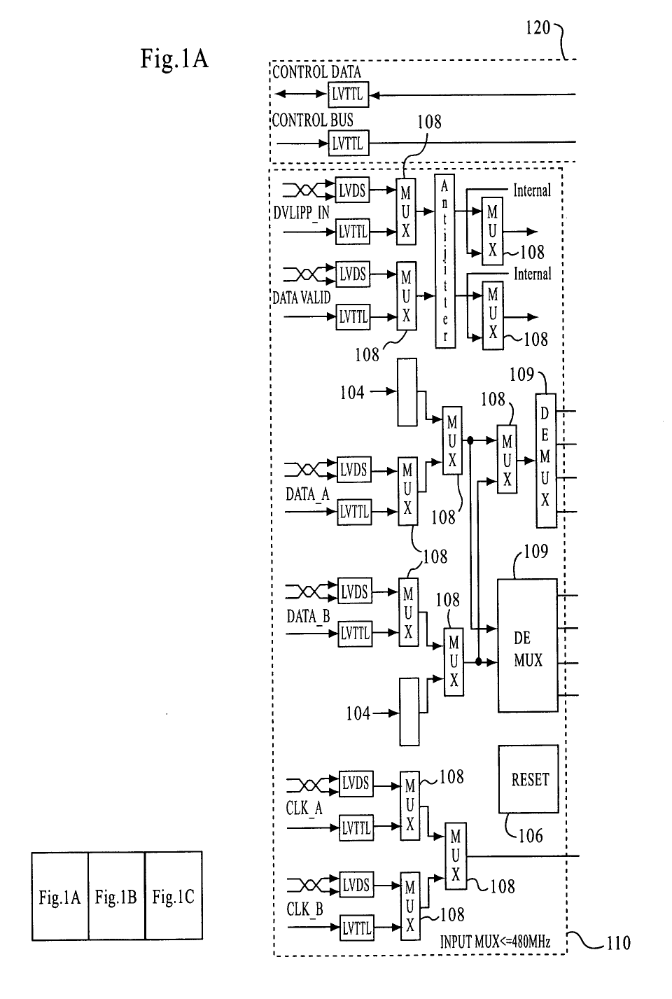

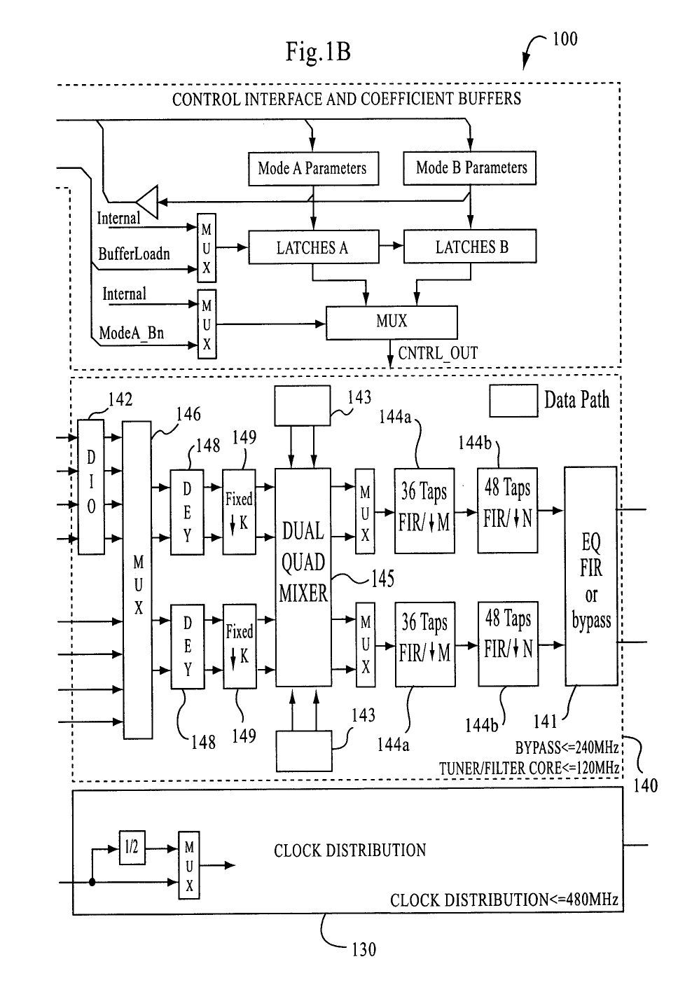

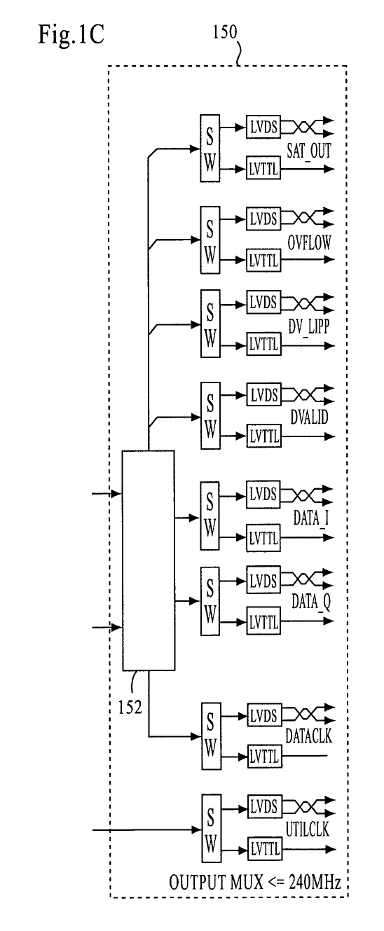

FIG. 1 is a block diagram of an exemplary digital receiver ASIC architecture according to an embodiment of the present invention. The ASIC architecture includes a high-performance, single-chip, digital signal processing device 100 optimized for down-conversion and filtering functions which were previously implemented with analog superheterodyne techniques.

The present invention is capable of performing all operations necessary for digital IQ (In-phase and Quadrature channel) signal generation, local oscillator (LO) synthesis, digital mixing, multi-stage filtering and decimation, passband equalization, integration & dump functions and DC offset adjustment. All internal functions preferably have a bypass mode that effectively disables the function to conserve electrical power in applications where one or more internal functions are not required. All filtering operations of the chip 100 (excluding the digital IQ generation) preferably have fully programmable coefficients and are double-buffered to allow a new set of coefficients to be loaded into the chip 100 while another set is in use. This provides the chip 100 with near-instantaneous reconfiguration when the receiver changes its mode of operation.

The chip 100 can preferably process IF sampled signals from a single A/D converter, or can process baseband IQ samples from a receiver that employs analog IQ generation via an RF quadrature mixer and pair of A/D converters. This allows the chip 100 to be used in IF-sampled receivers or baseband-sampled receivers.

Chip 100 can include a variety of electrical interfaces to allow the chip 100 to be used with single-ended or differential signals at many standard voltage levels. These features allow the chip 100 to be used, without modification, in a wide variety of applications. The chip 100 can also include built-in test signal generators 104 to support automatic built-in test, and global reset signals to clear all registers and signal paths.

As shown in the FIG. 1, the chip 100 is partitioned into five major sections: 1) input MUX 110,

2) control interface 120,

3) clock distribution 130,

4) tuner-filter core 140, and

5) output MUX 150. The following sections describe the functions and features of each of these stages.

Input Mux

The input MUX 110 provides the front-end interface to the input signals and clocks. There are three primary inputs: Data (A, B), Data Valid, and Last Interpulse Period (LIPP).

The Data signal (A, B) contains the digital samples from as many as two A/D converters, each with up to 16 bits of information. These two inputs can be used in three different ways, depending on the application. The first and most common method is for the A/D samples from an IF sampled receiver to supply one input and leave the second input unused. For systems that have dual IF sampled receivers, for example a narrowband receiver and another wideband receiver, the outputs from both receiver “front-ends” can be connected to the two Data inputs (Data-A, Data-B) of the chip 100, and one of these inputs can be electronically selected at a time. This allows a single chip to perform digital processing on one of two simultaneous receiver signals and to switch nearly instantaneously between them. The third configuration is to supply each input signal from an analog baseband receiver. With this type of receiver, RF circuitry can be used to create baseband signals that are then sampled by a pair of A/D converters. The digital IQ outputs of these converters can be input to the pair of Data (A, B) inputs on the chip 100. Each Data input, (A, B), has a corresponding Clock input (CLK_A, CLK_B) which supplies the ASIC with the proper timing for it's internal operations depending on the data rate of the selected Data input (A, B).

The Data inputs (A, B) can accept data in either 2's complement or offset binary form—depending on the type of A/D converter connected thereto. In addition, the Input MUX module 110 contains programmable saturation detection circuits that, in the absence of an external A/D saturation bit, will declare input saturation if the programmable signal limits are exceeded.

A Data Valid input is provided on the chip 100. The Data Valid signal is a simple logic 0-1 signal which tells the chip 100 when to process or ignore the input Data (A, B). This allows the chip 100 to remain idle during power-up transients or other conditions that might introduce spurious or unwanted signals in the chip 100. It also allows some external controller the ability to process and collect data only during selected time intervals.

The LIPP signal (DVLIPP_IN) is another logic 0-1 signal that is used to synchronize external devices. The LIPP signal does not undergo any signal processing other than to delay it by an amount equal to the processing delay of the input data. This feature allows external synchronization signals to remain synchronized to the output data as the data is delayed through various (programmable) signal processing functions.

The Input MUX block 110 also contains reset circuitry 106 and pattern generators 104 for testing the chip 100. It also contains circuitry (not shown) to detect when the input signals are at (or near) saturation. This saturation flag is propagated throughout the chip 100 and eventually output to indicate to subsequent devices that a saturation condition has occurred and the output data is possibly corrupted.

All of the complex switching between inputs and clocks (clock signals) is accomplished with a set of MUXes (multiplexers) 108. After the inputs and clocks are selected, they are commutated into four parallel data paths using DEMUX circuitry 109. The commutated data paths operate at one-fourth the data rate of the primary input. This is a key feature that allows the chip to process up to 240 MHz of bandwidth without loss of information, using circuits that only operate at 60 MHz (or, e.g., 480 MHz with 120 MHz circuits, etc.).

Control Interface

The Control Interface 120 provides the necessary electrical interfaces to the chip 100 to allow an external controller to reset the chip 100, load coefficients and other constants such as for filtering, configure the chip 100 by enabling or disabling bypass setting on each function, switch the chip between two processing modes, switch the input between two A/D inputs, and test the chip 100.

One novel feature of the control interface 120 is the ability to instantaneously switch between two chip modes (or configurations) while preloading another pair of configurations. In operation, a pair of preloaded configurations, for example configurations “A” and “B”, can be selected instantaneously. While the chip 100 is processing in either configurations A or B, another set of configurations (call e.g., configurations “C” and “D”) can be loaded. Upon command, the new (C, D) configurations can be made active, and the chip 100 can be switched between them instantaneously. While the C,D configurations are active, another set of configurations (e.g., E, F) can be loaded, and the process repeated ad infinitum. This feature is referred to as a double-buffered A/B switch. All programmable parameters (coefficients, offsets, tuner frequencies, bypass settings, etc.) in the chip 100 preferably include this feature.

Clock Distribution

The Clock Distribution block 130 accepts the selected input clock (i.e., from clock A or B) and distributes the necessary copies (possibly decimated) throughout the chip 100. The clock distribution circuit 130 also generates a Utility Clock signal (UTILCLK) that is output from the chip 100. The Utility Clock can be used by other external devices to synchronize to the chip's 100 output data. The chip 100 can process input data rates as high as 480 MHz for IF-sampled inputs, or 240 MHz for baseband-sampled inputs.

Output MUX

The Output MUX 150 provides the electric interface to external circuits that receive signals from this chip 100. It selectively provides either single-ended or differential signals for all outputs. Outputs can include: IQ signals (Data-I, Data-Q), Data Valid (DVALID) and Last IPP (DV-LIPP) (delayed to match the IQ data delay), Saturation Bit (SAT-OUT) (also delayed to align with the IQ data), Overflow Detection Bit (OVFLOW) (indicating on a sample-by-sample basis if any internal arithmetic overflows occurred), Data Clock (DATACLK) (at the same rate and synchronized with the output data), and Utility Clock UTILCLK) (high speed clock also synchronized with the data).

The data output is preferably fixed-point, 16-bit, 2's complement (or offset binary). The output MUX 150 also includes Integrate & Dump and DC Offset Correction Circuit 152. Integrate & Dump circuitry 152 sums up to 255 consecutive IQ samples before outputting data. After data is output, the integrator is reset and integration begins anew. The number of samples integrated is preferably fully programmable (as described above) from 0 to 255. The Integrate & Dump circuit 152 also employ an autoscaling circuit (not shown) to scale the integrated signal amplitude to be within limits prescribed by the digital output word size.

The DC Offset Correction circuit 152 adds (or subtracts) a user-programmable constant (e.g. DC) value from the I and Q channels. Typically, this offset is used to compensate for low-level analog leakage of the LO signal before downconversion and sampling by the A/D converter.

Tuner Filter Core

The Tuner Filter 140 accepts demuxed data from the Input MUX 110 and performs digital tuning and filtering. The primary functions of the Tuner Filter 140 include: Digital IQ (DIQ) Generation 142, DIQ/Baseband MUX 146, Coarse Time Delay 148, Fixed Decimation 149, Digital Tuning via Numerically Controlled Oscillator (NCO) 143 and Digital Mixer 145, Two-Stage FIR Filtering 144, IQ Balance, IQ Swap, and Complex Channel Equalization 141.

DIQ circuit 142 is used to convert a real IF-sampled signal into a complex baseband signal. This DIQ circuit 142 takes the real IF samples and mixes them with a complex (real and imaginary) local oscillator running at the IF center frequency. This mixing operation effectively downconverts the signal from IF to baseband. An image signal caused by the mixing operation is filtered out with a pair of lowpass FIR filters 142.

DIQ circuit 142 operates on the 1:4 demuxed input signal and performs all of its internal computations using multirate signal processing techniques. This allows the circuit to process a full bandwidth signal with circuits that operate no faster than quarter bandwidth. In the process of downconversion, the IQ output signals are decimated by two—all of the secondary output samples are discarded and only the primary ones are output to the subsequent circuitry.

The DIQ circuit 142 contains the necessary internal functions to properly handle cases where the user wants to keep the secondary samples and discard the primary ones. A user-controlled switch, called Odd PRF (not shown), allows the user to select whether to keep the primary or secondary samples of the DIQ output. Novel aspects of this circuit are described elsewhere in this patent document.

The DIQ/Baseband MUX 146 selects either the output of the DIQ circuit 142, or a set of equivalent samples from an analog (baseband) sampled receiver (Data B). Both inputs consist of 4 data paths: even 1, odd 1, even Q, and odd Q. Each of these paths operates preferably at 60 MHz, but could be more or less depending on the input A/D sample rate.

The Coarse Time Delay circuits 148 are tapped delay line structures that delay the IQ channels by a programmed amount of time—in increments of the basic clock period (typically 60 MHz). This feature allows multiple receivers that are processing a common signal, when one received signal is delayed due to RF propagation through the atmosphere or the RF receiver, to align the signals (coarsely) in time. The coarse time delay is selectable from 0 to 7 samples. Fine time delay adjustment can be made in the subsequent FIR filter stages 144.

Fixed Decimation circuit 149 performs sample decimation on the IQ paths by a user-specified amount of 1, 2, or 4. (A value of 1 is equivalent to no decimation). Fixed decimation is used when the input IF bandwidth is oversampled by the A/D converters, and it is now desired to reduce the sample rate to be commensurate with the bandwidth.

Dual Quad Mixer 145 comprises a digital mixer (e.g. multiplier) that mixes the input IQ samples with a local oscillator 143 to shift the signal frequency. This process is also referred to as digital tuning. Digital tuning is useful for several reasons. One use of digital tuning is to eliminate a strong DC value at zero frequency. If the desired passband of the signal is adjusted in the RF receiver such that it is offset from baseband after DIQ, and if there is a strong DC value at zero, then the DC can be eliminated by tuning the signal to zero and by applying a low-pass filter (using the FIR filters discussed below). The DC value will be reduced to the stopband attenuation level of the filter.

Another use of the mixer is to compensate for Doppler shift of clutter. Many airborne radar systems employ a simple clutter mitigation circuit that effectively puts a notch filter at zero Doppler frequency. This eliminates mainbeam clutter if the radar beam is aligned with the velocity vector of the aircraft. However, as the radar beam is scanned away from the velocity vector, the clutter shifts in Doppler and moves out of the notch. The digital tuner can be used to shift the clutter spectrum back to zero frequency where it will once again be eliminated by the clutter notch. The tuner can also be used to select different “channels” from within the overall receiver passband. This allows the system, for example, to receive selected transmit waveforms in a multistatic radar system.

The Dual Quad Mixer 145 is preferably simply a quadrature (i.e. complex) mixer that multiplies incoming IQ samples with a tunable (also complex) local oscillator signal. The local oscillator signals are synthesized by a numerically controlled oscillator (NCO) 143 that uses the CORDIC algorithm (COordinate Rotation DIgital Computer). The CORDIC (NCO) circuit 143 is well known and will not be elaborated on here. The CORDIC (NCO) circuit 143 was designed to provide a very spectrally-pure reference oscillator signal with a mere −160 dBc/Hz phase noise. It is controlled by a programmable frequency value that ranges from −120 MHz to +120 MHz. If the Dual Quad Mixer 145 is not needed, it can be bypassed with a user-controlled bypass switch. In addition, to support testing, the CORDIC oscillator signals can be injected directly into the mixer output. The input IQ samples are discarded in this configuration.

Following the mixer 145 are two stages of filtering and decimation. The first stage is a 36 tap FIR filter 144a with fully programmable coefficients and selectable decimation of 1, 2, 3, or 4. The second stage filters 144b are functionally identical to the first, except that they have 48 taps. The two stages together provide considerable flexibility is creating filters with the desired passband, transition band, and stopband characteristics. Arbitrary (real) coefficients can be loaded into the I and Q data paths. Typically, these coefficients are designed to implement a low-pass filter. By skewing these coefficients in time, fine time-delay adjustments can be made on the signal. While multistage, multirate FIR filtering is not a new concept, the circuit structure, which admits a programmable decimation, is novel.

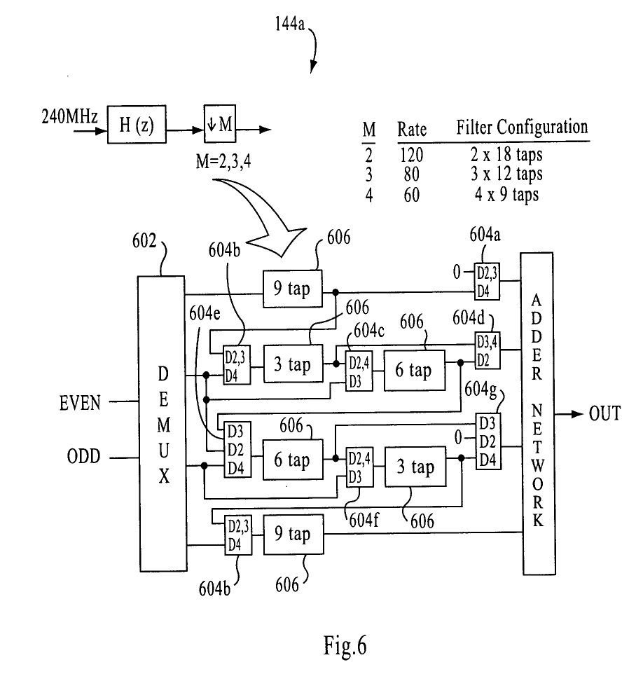

FIG. 6 shows the novel programmable architecture for a FIR filter. This FIR filter circuit 144a allows the outputs of the FIR filter to be decimated (down-sampled) by 2, 3, or 4, but because the FIR filter taps are reused via a novel switching arrangement, no computations are wasted. Former methods for decimating would have performed the FIR filtering computations at the input rate, then thrown away the output samples that are not needed. Thus, many computations done by the circuit would be wasted. In this circuit, only those samples that will be retained at the output are computed so no computations are wasted. Further, no matter how the input signals are down-sampled, the same number of taps is used.

The architecture shown in FIG. 6 specifically applies to the 36-tap FIR filter (144a). The same architecture (not shown) is used in the 48-tap FIR filter (144b) except that the filter internally is divided into 2×24 tap, or 3×16 taps, or 4×12 taps. The architecture is thus easily extended to include any FIR filter whose length is even divisible by 2, 3, and 4.

As can be seen, even and odd sampled inputs are demultiplexed (602) into 4 samples 0, 1, 2, and 3. A number of switches 604a-h route the signal through FIR filters 606 to achieve the down sampled signal. For example, at M=2 (the D2 switch ports are enabled), two signals are filtered at 18 taps and combined in the adder 608. The switches 604 are controlled by control logic (not shown) in order to achieve the desired decimation while maintaining constant the number of taps used to filter the signals.

After FIR filtering, the architecture performs IQ Swap and IQ Balance. (These are not shown explicitly on the block diagram because they have been integrated with the Equalization filter function 141 that follows.) The IQ Swap circuit basically interchanges the I and Q data paths. This is used to compensate for RF receiver designs that use “high-side” versus “low-side” local oscillators in their downconversion circuits. The result is that a signal that increases in RF frequency may actually appear to decrease in frequency after RF downconversion. This effect is negated completely by swapping IQ samples. Also, if the Odd PRF switch is selected in the DIQ circuit, it will be necessary to adjust the phase of the IQ samples using the IQ Swap circuit.

The IQ Balance circuit is used to adjust the gain and phase of the in-phase and quadrature signals to maintain exactly 90 deg phase difference and equal amplitudes. This circuit is used in receivers that employ analog IQ generation with a pair of A/D converters. In these systems, the IQ outputs can become distorted due to electrical differences in the A/D converters and the RF circuitry that precedes them.

The IQ Balance circuit includes effectively a matrix-multiplication circuit. The input IQ “vector” is multiplied by a 2×2 complex matrix to yield an output IQ “vector”. The coefficients in the 2×2 matrix are obtained via a calibration procedure in which the distorted IQ samples are recorded and analyzed off-line. The proper matrix coefficients are such that after matrix multiplication, the output IQ samples have had the gain and phase distortions eliminated or at least minimized.

The Equalization (EQ) FIR 141 is preferably a complex FIR filter which is used to perform a frequency-dependant gain and phase adjustment to compensate for undesired characteristics of the (analog) IF amplifier and filter. Typically, due to manufacturing tolerances, analog parts exhibit different gain and phase characteristics from one receiver to the next. The EQ FIR 141 can digitally correct these passband distortions by applying frequency-dependant gain and phase adjustments.

An exemplary EQ FIR 141 has 15 complex coefficients, so the passband can be corrected at up to 15 discrete frequencies within the passband. The coefficients are determined by calibration during which a signal is swept across the passband, and output samples are collected and analyzed offline. A set of up to 15 complex coefficients are derived which when applied to the input signal, yields a passband with nearly matches a reference passband (presumably another receiver). The difference between such a pair of receivers can be less than −60 dBc. The output of the equalization FIR goes to the Output MUX section for final integration and distribution off chip.

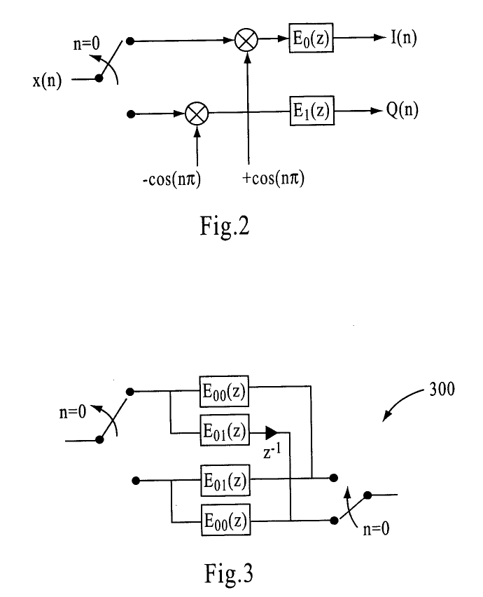

The present invention provides a novel general method for implementing the DIQ function using circuits which are limited to R adds or multiplies per second, but which can process input sample rates of 4R or 8R or higher without loss of any Nyquist bandwidth. Thus, ASICs which can perform adds or multiplies at only 120 MHz, for example, could be used to process 960 MHz input data rates without any loss of information. The method can be extended to process even higher data rates (using the same circuit technology) at the expense of larger overall circuits. Former low-speed methods for implementing DIQ are shown in FIG. 2.

The key to implementing a high speed DIQ is a novel structure for high-speed FIR filtering. These high-speed FIR filters can then be implemented in the circuit of FIG. 2 to yield a high-speed DIQ.

The result is a circuit which overall is larger than the original circuit, so it is not efficient in terms of circuit utilization. However, the important point is that by utilizing redundant circuits in parallel, processing of 2R samples-per-second (or more) can be performed using circuits which only run at R samples per second—and without loss of information in the process.

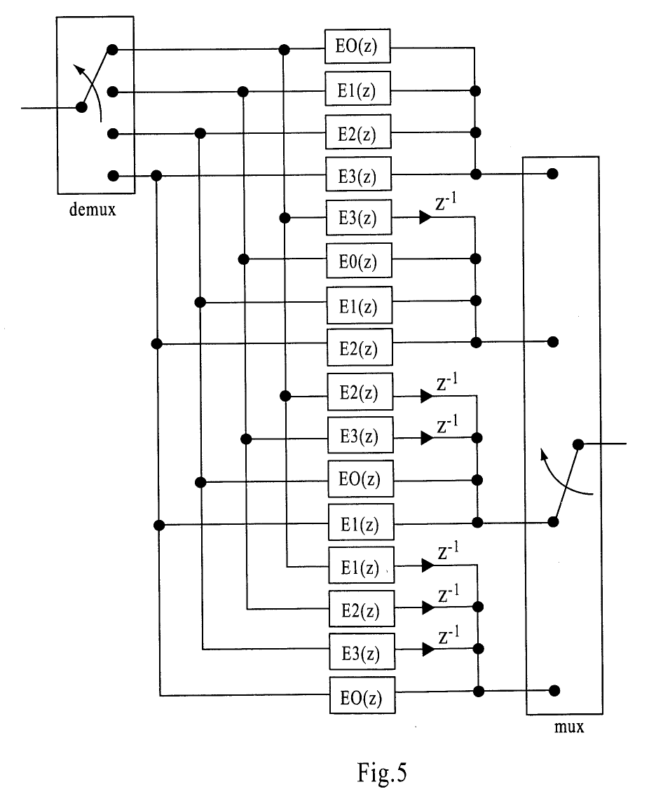

FIG. 3 shows the novel implementation of a 2R FIR filter according to an embodiment of the present invention. This FIR filter inputs data at 2R samples per second, performs all internal computations (adds and multiplies) at R samples per second, then outputs a full 2R data rate. There are no restrictions on the number of taps or filter shape characteristics of the FIR filter. Functionally, this circuit is exactly equivalent to a FIR filter in which all computations are performed at the full R) data rate. The same methodology can be employed to yield FIR filters with process data rates of 4R samples-per-second, as shown in FIG. 5.

Note that the overall circuit is now 4 times bigger than the original circuit. This circuit growth should not be construed as a fundamental limitation of this approach. Modern ASICs have far more gates and transistors than can be powered at these high data rates. Power dissipation is a fundamental limitation—not circuit size. It is more efficient to use more gates running at slower speed than to use fewer gates at high speed.

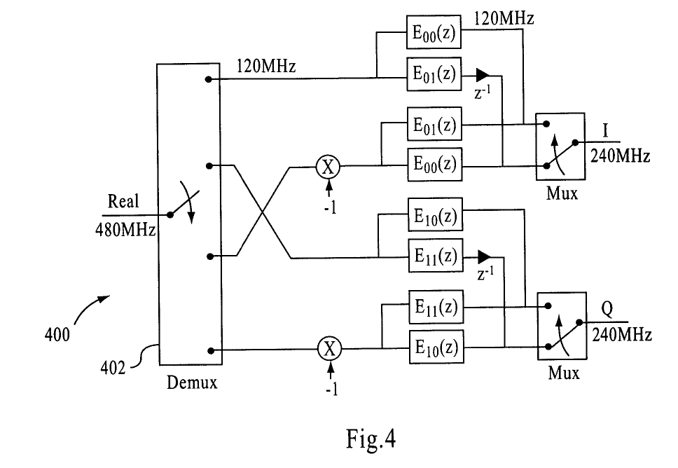

The present invention uses the 4R architecture to create the DIQ circuit shown in FIG. 4. The circuit 400 preferably supports inputs of digital data at rates up to 480 MHz. The output is in-phase and quadrature samples at 240 MHz each. As shown, the input (Real signal) in demultiplexed by demux 402 into four signals, two of which are inverted. All the signals are split again and filtered. The inverted signals are combined with non-inverted signals and multiplexed into the I and Q channels. Delays are used to line up the signals.

The filter coefficients are based on a 32-tap prototype filter H(z) shown in Table 1 below. The filter coefficients of H(z) are partitioned into two sets E₀(z) and E₁(z) such that E₀(z) has all of the even-numbered coefficients of H(z), and E₁(z) has all the odd-numbered coefficients. Then, E₀(z) is further partitioned into a subfilter E₀₀(z) that has all the even coefficients of E₀(z), and a subfilter E₀₁(z) that has all the odd coefficients. The same partitioning is applied to E₁(z) to yield subfilters E₁₀(z) and E₁₁(z). Note that all of the subfilters occur twice in the circuits of FIGS. 3 and 4. Thus, the overall circuit is twice as big as the prototype filter H(z). This is the results from processing a data rate of 2R samples-per-second with circuits that only run at R samples-per-second. The coefficients for the subfilters E₀₀(z), E₀₁(z), E₁₀(z), and E₁₁(z) are also listed in Table 1. All inputs, coefficients and outputs are 16-bit two's complement digital words.

TABLE 1
Filter Prototype and Subfilter Coefficients.

| index | H(z) | E₀₀(z) | E₀₁(z) | E₁₀(z) | E₁₁(z) |
|---|---|---|---|---|---|
| 0 | −10 | −10 | | | |
| 1 | 45 | | | 45 | |
| 2 | 140 | | 140 | | |
| 3 | −13 | | | | −13 |
| 4 | −350 | −350 | | | |
| 5 | −73 | | | −73 | |
| 6 | 736 | | 736 | | |
| 7 | 311 | | | | 311 |
| 8 | −1366 | −1366 | | | |
| 9 | −829 | | | −829 | |
| 10 | 2390 | | 2390 | | |
| 11 | 1925 | | | | 1925 |
| 12 | −4297 | −4297 | | | |
| 13 | −4747 | | | −4747 | |
| 14 | 10314 | | 10314 | | |
| 15 | 28649 | | | | 28649 |
| 16 | 28649 | 28649 | | | |
| 17 | 10314 | | | 10314 | |
| 18 | −4747 | | −4747 | | |
| 19 | −4297 | | | | −4297 |
| 20 | 1925 | 1925 | | | |
| 21 | 2390 | | | 2390 | |
| 22 | −829 | | −829 | | |
| 23 | −1366 | | | | −1366 |
| 24 | 311 | 311 | | | |
| 25 | 736 | | | 736 | |
| 26 | −73 | | −73 | | |
| 27 | −350 | | | | −350 |
| 28 | −13 | −13 | | | |
| 29 | 140 | | | 140 | |
| 30 | 45 | | 45 | | |
| 31 | −10 | | | | −10 |

The approach described above allows creation of in-phase and quadrate signals with very low images over bandwidth 3 to 4 times wider than current approaches. The architecture for the circuit is scalable and can support even wider bandwidths than disclosed here. As a result, efficient processing of digital data is capable at rates well over 1 billion samples-per-second.

Thus, a number of preferred embodiments have been fully described above with reference to the drawing figures. Although the invention has been described based upon these preferred embodiments, it would be apparent to those of skill in the art that certain modifications, variations, and alternative constructions could be made to the described embodiments within the spirit and scope of the invention.

We claim:

1. An integrated circuit on a single chip, comprising:
a module for digital IQ generation;
a module for LO synthesis;
a digital mixing module;
a multi-stage filtering and decimation module;
a passband equalization module;
an integrate & dump module; and
a DC offset adjustment module.

2. The integrated circuit of claim 1, wherein filtering operations have fully programmable coefficients that are double-buffered to provide near instantaneous selection between a pair of coefficient sets and to allow a second set of coefficients to be loaded while a first set of coefficients are in use.

3. The integrated circuit of claim 1, comprising a plurality of electrical interfaces to allow the chip to be used with single-ended or differential signals at a plurality of voltage levels.

4. The integrated circuit of claim 1, configured to process intermediate frequency (IF) sampled signals from a single A/D converter and to process baseband IQ samples from a receiver that employs analog IQ generation via an radio-frequency (RF) quadrature mixer and pair of A/D converters.

5. An integrated circuit on a single chip, comprising:
input MUX means for providing front-end interface to the input signals and clock signals;
control Interface means for providing electrical interfaces to allow an external controller to reset the chip, load coefficients, configure the chip by enabling or disabling bypass setting on a plurality of functions, switch between at least two processing modes, switch between at least two A/D inputs, and test the chip;
clock distribution means for accepting a selected input and distributing copies of the selected input throughout the chip, generating a utility clock signal (UTILCLK) output from the chip to be used by other external devices to synchronize to output data of the chip;
output MUX means for providing an electric interface to external circuits that receive signals from the chip, and selectively providing either single-ended or differential signals for all outputs; and
tuner filter means for accepting demuxed data from the input MUX means and performing digital tuning and filtering.

6. The integrated circuit of claim 5, wherein the tunable filter means provides at least one function from the group comprising Digital IQ (DIQ) Generation, DIQ/Baseband MUX, Coarse Time Delay, Fixed Decimation, Digital Tuning via Numerically Controlled Oscillator (NCO), Digital Mixer, Two-Stage FIR Filtering, IQ Balance, IQ Swap, and Complex Channel Equalization.

7. The integrated circuit of claim 5, wherein said output MUX means ouptuts IQ signals (Data-I, Data-Q), Data Valid (DVALID) and Last IPP (DV-LIPP) (delayed to match the IQ data delay), Saturation Bit (SAT-OUT) (delayed to align with the IQ data), Overflow Detection Bit (OVFLOW), Data Clock (DATACLK) at the same rate and synchronized with the output data, and Utility Clock UTILCLK).

8. A reconfigurable filter and decimate circuit, comprising:
a signal input;
an adder coupled having a plurality of signal inputs and a signal output;
means for demultiplexing a signal received into a plurality of sampled signals;
a plurality of FIR filters each having a number of taps; and
switching means for coupling said plurality of sampled signals with said plurality of FIR filters and with said plurality of signal inputs to said adder, and for decimating said input signal a number of times, and for each number of times, the output of said adder is filtered by the same number of taps.

9. The filter and decimate circuit as recited in claim 8, wherein said means for demultiplexing said signal separates said input signal into four signals comprising first and second odd sampled signals and first and second even sampled signals.

10. The filter and decimate circuit as recited in claim 8, wherein the number of taps in said FIR filters combines to be 36 taps, and each of said FIR filters comprise 3, 6 or 9 taps.

11. The filter and decimate circuit as recited in claim 9, wherein the number of taps in said FIR filters combines to be 36 taps, and each of said FIR filters comprise 3, 6 or 9 taps.

12. The integrated circuit as recited in claim 1, wherein said multi-stage filtering and decimation module includes a reconfigurable filter and decimate circuit, comprising:
a signal input;
an adder coupled having a plurality of signal inputs and a signal output;
means for demultiplexing a signal received into a plurality of sampled signals;
a plurality of FIR filters each having a number of taps; and
switching means for coupling said plurality of sampled signals with said plurality of FIR filters and with said plurality of signal inputs to said adder, and for decimating said input signal a number of times, and for each number of times, the output of said adder is filtered by the same number of taps.

13. The integrated circuit as recited in claim 5, wherein said tuner filter means includes a reconfigurable filter and decimate circuit, comprising:
a signal input;
an adder coupled having a plurality of signal inputs and a signal output;
means for demultiplexing a signal received into a plurality of sampled signals;
a plurality of FIR filters each having a number of taps; and
switching means for coupling said plurality of sampled signals with said plurality of FIR filters and with said plurality of signal inputs to said adder, and for decimating said input signal a number of times, and for each number of times, the output of said adder is filtered by the same number of taps.

14. A fast FIR filter comprising:
a demultiplexer configured to receive an input signal and to separate the signal into a plurality of signals;
filter means for filtering the plurality of signals and outputting a plurality of filtered signals; and
a multiplexer for combing the plurality of filtered signals into a single output signal;
wherein said filter means processes each said plurality of signals at a rate a plurality of times slower than the input rate of said input signal without decimation of said input signal and without loss of bandwidth of said input signal.

15. The fast FIR filter as recited in claim 14, wherein said input signal has a data rate of 4R, said demultiplexer splits said input signal into four signals, said filter means processes each of said four signals at a data rate of R, and said single output signal has a data rate of 4R.

16. The integrated circuit as recited in claim 1, wherein said multi-stage filtering and decimation module includes a fast FIR filter comprising:
a demultiplexer configured to receive an input signal and to separate the signal into a plurality of signals;
filter means for filtering the plurality of signals and outputting a plurality of filtered signals; and
a multiplexer for combing the plurality of filtered signals into a single output signal;
wherein said filter means processes each said plurality of signals at a rate a plurality of times slower than the input rate of said input signal without decimation of said input signal and without loss of bandwidth of said input signal.

17. The fast FIR filter as recited in claim 14, further comprising splitting circuitry for splitting said plurality of signals into a plurality of groups of signals; said filter means includes, for each of groups of signals being filtered, a group of filters.

18. The fast FIR filter as recited in claim 17, wherein said demultiplexer splits said input signal into first, second, third and fourth input signals; and
wherein said plurality of groups of signals includes first, second, third and fourth groups, and each of said groups includes first, second, third and fourth signals corresponding respectively to said first, second, third and fourth input signals; and
wherein for each group of signals, said first, second, third and fourth signals are filtered by one of first, second, third and fourth FIR filters, the output of the filters is combined into a single filtered signal for each group and input into said multiplexer.

19. The fast FIR filter of claim 18, wherein for said first group, said first signal is filtered by said first filter, said second signal is filtered by said second filter, said third signal is filtered by said third filter, and said fourth signal is filtered by said fourth filter; and
wherein for said second group, said first signal is filtered by said fourth filter, said second signal is filtered by said first filter, said third signal is filtered by said second filter, and said fourth signal is filtered by said third filter; and
wherein for said third group, said first signal is filtered by said third filter, said second signal is filtered by said fourth filter, said third signal is filtered by said first filter, and said fourth signal is filtered by said second filter; and
wherein for said fourth group, said first signal is filtered by said second filter, said second signal is filtered by said third filter, said third signal is filtered by said second filter, and said fourth signal is filtered by said first filter.

20. The fast FIR filter of claim 19, further comprising delay means for delaying some of said filtered signals in order to generate a homogenous filtered output signal.

21. A digital IQ signal generation circuit, comprising:
demultiplexing means for separating a real input signal into first, second, third and fourth signals;
inverter means for inverting said third and fourth signals;
low pass FIR filter means for filtering said first, second, third and fourth signals; and
multiplexing means for combining the filtered first and third signals and for combining said second and fourth signals, in order to generate I and Q sampled signals at one half an input data rate of said real input signal; wherein
said low pass FIR filter means processes signals at one quarter the input data rate of said real input signal.

22. The integrated circuit as recited in claim 1, wherein said module for digital IQ generation includes a fast FIR filter comprising:
a demultiplexer configured to receive an input signal and to separate the signal into a plurality of signals;
filter means for filtering the plurality of signals and outputting a plurality of filtered signals; and
a multiplexer for combing the plurality of filtered signals into a single output signal;
wherein said filter means processes each said plurality of signals at a rate a plurality of times slower than the input rate of said input signal without decimation of said input signal and without loss of bandwidth of said input signal.

23. The integrated circuit of claim 1, wherein each function includes a bypass mode that effectively disables the function to conserve power in applications where one or more functions are not required.
